(19) United States
(12) Patent Application Publication
(10) Pub. No.: US 2012/0013401 A1
(43) Pub. Date: Jan. 19, 2012

(54) POWER AMPLIFIER WITH SELECTABLE LOAD IMPEDANCE AND METHOD OF AMPLIFYING A SIGNAL WITH SELECTABLE LOAD IMPEDANCE

(75) Inventors: Moon-Suk JEON, Seoul (KR); Chan Hoe KOO, Gunpo-si (KR); Hyung Bin LEE, Seoul (KR); Sang Hwa JUNG, Ansan-si (KR)

(73) Assignee: Avago Technologies Wireless IP (Singapore) Pte. Ltd., Singapore (SG)

(21) Appl. No.: 12/835,853

(22) Filed: Jul. 14, 2010

(51) Int. Cl. H03F 1/30

(52) U.S. Cl. 330/192

(57) ABSTRACT

A device includes: a power amplifier, including a supply voltage terminal, an input port and an output port, and the power amplifier being configured to receive a supply voltage at the supply voltage terminal, an input signal through the input port, to amplify the received input signal, and to output an amplified output signal through the output port; a variable impedance matching circuit having an input terminal connected to the output port of the power amplifier, and having an output terminal for being connected to a load; and a controller including a voltage measuring unit configured to measure the supply voltage, to compare the measured supply voltage with a threshold voltage, and to control the variable impedance matching circuit based on a result of the comparison so as to adjust a load impedance seen by the power amplifier at its output port.

### BACKGROUND

The present invention relates to a method and apparatus for amplifying a signal.

As the size of a portable electronic device such as a cellular phone is an important design factor, so also is the capacity or size of a battery installed therein to power the device. Consequently, the power consumption of elements incorporated in the portable electronic device becomes subject to power-efficient design requirements. Such requirements calling for a high power efficiency often become even more stringent in the case of a complicated portable electronic device, such as a smartphone, employing a large number of elements to provide a greater variety of features and functions. In particular, among all the heavy power consuming elements in a portable electronic device, controlling the power efficiency of a power amplifier is important since it operates all the time while the portable electronic device is powered on and its communication capabilities are enabled.

In designing a power amplifier, the linearity thereof is another important factor in addition to the power efficiency. For instance, on parameter that is often important for a power amplifier is the level of harmonic distortion generated by the power amplifier. Communications systems employing complicated schemes such as HSDPA (High Speed Downlink Packet Access), HSUPA (High Speed Uplink Packet Access), LTE (Long Term Evolution) or the like require high linearity, and often implemented with, for example, a large back-off in order to address the strict linearity requirement.

However, it has been a major challenge to design a power amplifier to satisfy both high linearity requirements and power efficiency requirements. That is, if a power amplifier is designed to have high linearity, the power efficiency thereof tends to be reduced and vice versa. For instance, a Class A power amplifier has a comparatively good linearity but a relatively poor power efficiency. In contrast, a Class B power amplifier has a comparatively good power efficiency but a rather poor linearity. Thus, engineers have had to settle with a compromise to design a power amplifier having a linearity and a power efficiency capable of achieving certain respective levels.

### SUMMARY

It is, therefore, an object of the present invention to provide a method and apparatus for amplifying a signal that addresses both linearity requirements and power efficiency requirements.

In accordance with one aspect of the invention, there is provided a device comprising: a power amplifier, including a supply voltage terminal, an input port and an output port, and the power amplifier being configured to receive a supply voltage at the supply voltage terminal, an input signal through the input port, to amplify the received input signal, and to output an amplified output signal through the output port; a variable impedance matching circuit having an input terminal connected to the output port of the power amplifier, and having an output terminal for being connected to a load; and a controller including a voltage measuring unit configured to measure the supply voltage, to compare the measured supply voltage with a threshold voltage, and to control the variable impedance matching circuit based on a result of the comparison so as to adjust a load impedance seen by the power amplifier at its output port.

In accordance with another aspect of the invention, there is provided a method of amplifying a signal. The method comprises: providing the signal to an input port of a power amplifier; providing a supply voltage to the power amplifier; amplifying the signal with the power amplifier and outputting an amplified output signal at an output port of the power amplifier; measuring the supply voltage; comparing the measured supply voltage with a threshold voltage; and adjusting a load impedance seen by the power amplifier at its output port based on a result of the comparison.

In accordance with yet another aspect of the invention, there is provided a device comprising: a power amplifier, including a supply voltage terminal, an input port and an output port, and the power amplifier being configured to receive a supply voltage at the supply voltage terminal, an input signal through the input port, to amplify the received input signal, and to output an amplified output signal through the output port; and circuitry configured to adjust a load impedance seen by the power amplifier at its output port, wherein when the supply voltage has a first voltage value the circuitry adjusts the load impedance to have a first impedance value, and when the supply voltage has a second voltage value less than the first voltage value, the circuitry adjusts the load impedance to have a second impedance value less than the first impedance value.

### BRIEF DESCRIPTION OF THE DRAWINGS

The above and other objects and features of the present invention will become apparent from the following description of embodiments given in conjunction with the accompanying drawings, in which:

FIG. 1 illustrates a magnitude of an output voltage supplied to a power amplifier from a battery, varying with time.

FIG. 2 is a block diagram showing a schematic construction of one embodiment of a signal amplifier.

FIG. 3 shows on a current-voltage plane an exemplary characteristic curve of a general power amplifier and a change of an exemplary load line.

FIG. 4A provides a first embodiment of a variable impedance matching circuit.

FIG. 4B exhibits on a Smith chart a change in the magnitude of a load impedance presented to a power amplifier by the variable impedance matching circuit of FIG. 4A depending on control of a switch.

FIG. 5A presents a second embodiment of a variable impedance matching circuit.

FIG. 5B displays on a Smith chart a change in the magnitude of a load impedance presented to a power amplifier by the variable impedance matching circuit of FIG. 5A depending on control of a switch.

FIG. 6A represents a third embodiment of the variable impedance matching circuit.

FIG. 6B depicts on a Smith chart a change in the magnitude of a load impedance presented to a power amplifier by the variable impedance matching circuit of FIG. 6A depending on control of a varactor diode.

FIG. 7 is a block diagram showing a schematic construction of another embodiment of a signal amplifier.

FIG. 8 demonstrates an exemplary relationship between the temperature of a power amplifier and a threshold voltage for controlling a variable impedance matching circuit for the power amplifier.

### DETAILED DESCRIPTION

In the following detailed description, for purposes of explanation and not limitation, example embodiments disclosing specific details are set forth in order to provide a thorough understanding of an embodiment according to the present teachings. However, it will be apparent to one having ordinary skill in the art having had the benefit of the present disclosure that other embodiments according to the present teachings that depart from the specific details disclosed herein remain within the scope of the appended claims. Moreover, descriptions of well-known apparati and methods may be omitted so as to not obscure the description of the example embodiments. Such methods and apparati are clearly within the scope of the present teachings.

Unless otherwise noted, when a first device is said to be connected to a second device, this encompasses cases where one or more intermediate devices may be employed to connect the two devices to each other. However, when a first device is said to be directly connected to a second device, this encompasses only cases where the two devices are connected to each other without any intermediate or intervening devices. Similarly, when a signal is said to be coupled to a device, this encompasses cases where one or more intermediate devices may be employed to couple the signal to the device. However, when a signal is said to be directly coupled to a device, this encompasses only cases where the signal is directly coupled to the device without any intermediate or intervening devices

Hereinafter, certain preferred embodiments of the present invention will be described in detail with reference to the accompanying drawings.

The inventors have recognized the following. When a battery supplies an output voltage to a device (e.g., a mobile phone) including power amplifier, the output voltage does not remain constant: as the electric energy charged in the battery is consumed, the output voltage decreases. On the other hand, since the power amplifier is designed to meet a minimum linearity requirement so as to ensure the power amplifier to operate normally even when the output voltage becomes low, there tends to exist an excess linearity over the minimum linearity requirement when the output voltage is comparatively high. Such excess linearity may entail an undesirable or unnecessary sacrifice in the power efficiency.

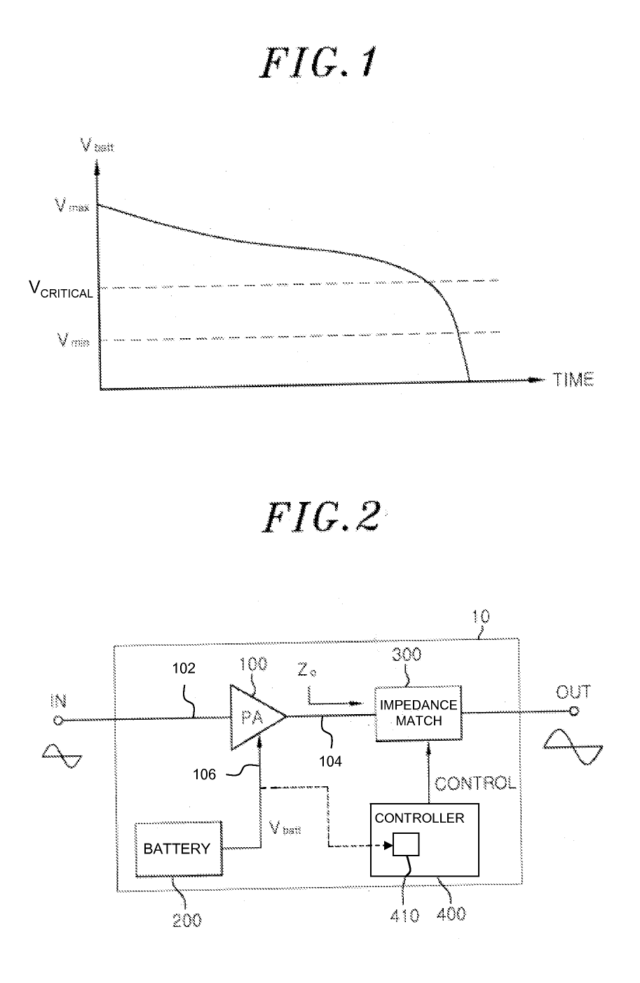

FIG. 1 illustrates how a magnitude of a battery supply voltage, V_{SUPPLY}, varies with time between recharges. When the battery is fully charged, the maximum magnitude of the supply voltage V_{SUPPLY} is denoted by V_{MAX}. As the battery supplies the supply voltage V_{SUPPLY} to a device including a power amplifier, over time the magnitude of the supply voltage V_{SUPPLY} decreases. The minimum magnitude of the supply voltage V_{SUPPLY} at which the power amplifier is still required to meet its minimum linearity requirement so as to ensure the power amplifier operates normally is denoted by V_{MIN}. Since the power amplifier is not required or expected to operate normally in a situation where the magnitude of the supply voltage V_{SUPPLY} falls below V_{MIN}, the power amplifier may be designed to stop its operation in such a situation or to notify a user of such a situation.

Since the minimum magnitude of the supply voltage V_{SUPPLY} which meets the minimum linearity requirement ensuring the power amplifier operates normally is V_{MIN} as set forth above, an excess linearity of the power amplifier over the minimum linearity requirement is obtained during a range where the magnitude of the supply voltage V_{SUPPLY} is greater than V_{MIN}. Further, the larger that the supply voltage V_{SUPPLY} is, the larger the amount of excess linearity that exists for the power amplifier. Recognizing that there is a trade-off between linearity and power efficiency, it can be expected that when the excess linearity becomes large due to the supply voltage V_{SUPPLY} having a large magnitude, the power efficiency of the power amplifier would be reduced. Embodiments of a device including a power amplifier will now be described which improve the power efficiency of the power amplifier by way of reducing the excess linearity during times when the supply voltage V_{SUPPLY} is significantly greater than V_{MIN}.

FIG. 2 schematically shows a construction of one embodiment of a signal amplifier 10. The signal amplifier 10 includes a power amplifier 100, a battery 200, a variable impedance matching circuit 300 and a controller 400. Power amplifier 100 includes an input port 102, an output port 104, and a supply voltage terminal 106. Supply voltage (or a drive voltage) V_{SUPPLY} is supplied to supply voltage terminal 106 from battery 200. Power amplifier 100 receives an input signal at input port 102 and amplifies the input signal to output an output signal at output port 104. The amplified signal is transmitted via variable impedance matching circuit 300 to a load, such as for example an antenna (not shown). Controller 400 has a voltage measuring unit 410 for measuring the supply voltage V_{SUPPLY} and controls variable impedance matching circuit 300 based on the measured supply voltage V_{SUPPLY}.

For example, signal amplifier 10 may be included in a portable electronic device, such as a cellular phone, and battery 200 may be a rechargeable battery of such a device for supplying the supply voltage V_{SUPPLY} to power amplifier 100. An exemplary operation of variable impedance matching circuit 300 controlled by controller 400 will be explained below in detail.

First, an appropriate value between V_{MAX} and V_{MIN}, is selected to be a threshold voltage, V_{CRITICAL}. The voltage measuring unit 410 measures the supply voltage V_{SUPPLY} and controller 400 controls variable impedance matching circuit 300 based on the measured supply voltage V_{SUPPLY} to adjust the magnitude of a load impedance Z_{O} which is seen by power amplifier 100 at its output port 104. In a particular embodiment, when the supply voltage V_{SUPPLY} lies between V_{MAX} and the threshold voltage V_{CRITICAL} controller 400 adjusts the magnitude of Z_{O} to be larger than the magnitude of the load impedance Z_{O} when the supply voltage V_{SUPPLY} lies between the threshold voltage V_{CRITICAL} and V_{MIN}. How the linearity and power efficiency of power amplifier 100 vary with the adjustment of the load impedance Z_{O} will be explained below in detail.

FIG. 3 illustrates on a current-voltage plane an exemplary characteristic curve C of a general power amplifier and exemplary load lines L₁ and L₂. If a load impedance of the power amplifier becomes larger, the load line changes from L₁ to L₂. Further, when the load line changes as above, the operating point also changes from O₁ to O₂ and both the current swing and the voltage swing become smaller. As a result of that, the output power of the power amplifier transferred to a load is also reduced, and the linearity of the power amplifier is decreased. On the other hand, since the dissipation power of the power amplifier is also reduced as the output power is reduced, the power efficiency of the power amplifier is improved. To sum up, by increasing the load impedance as seen by power amplifier 100 at its output port, power efficiency can be increased at the expense of reduced linearity.

Based on such a principle, when the supply voltage V_{SUPPLY} lies between V_{MAX} and the threshold voltage V_{CRITICAL}, controller 400 controls variable impedance matching circuit 300 to adjust the load impedance Z_{O} to have a comparatively large magnitude so that the linearity of power amplifier 100 is reduced, while the power efficiency thereof is increased. In a situation where the supply voltage V_{SUPPLY} is greater than the threshold voltage V_{CRITICAL}, an excess linearity exists and, therefore, there is no problem in meeting a minimum linearity requirement for normal operation of power amplifier 100 even if the linearity is somewhat reduced as described above. In contrast, when the supply voltage V_{SUPPLY} lies between the threshold voltage V_{CRITICAL} and V_{MIN}, controller 400 controls variable impedance matching circuit 300 to adjust the load impedance Z_{O} to have a comparatively small magnitude so that the linearity is increased and, thus, there occurs no problem in meeting the minimum linearity requirement for normal operation of power amplifier 100 even when the supply voltage V_{SUPPLY} is less than the threshold voltage V_{CRITICAL}.

As presented in FIG. 1 in general, it can be seen that the supply voltage V_{SUPPLY} of a battery decreases slowly for a certain period of time and then, for a remaining period of time the supply voltage V_{SUPPLY} decreases quickly. Further, in general the period of time where the supply voltage V_{SUPPLY} decreases slowly is much longer than the period of time of where the supply voltage V_{SUPPLY} decreases more rapidly. Therefore, if the threshold voltage V_{CRITICAL} is set in the vicinity of a point where the rate of which the supply voltage V_{SUPPLY} is decreasing changes abruptly from a lower rate to a higher rate, the power efficiency of the power amplifier 100 can be improved during most of the discharging time of battery 200 in which the supply voltage V_{SUPPLY} is larger than the threshold voltage V_{CRITICAL}.

Presented below are example embodiments of variable impedance matching circuit 300 which can be controlled by controller 400 to adjust the magnitude of the load impedance Z_{O}.

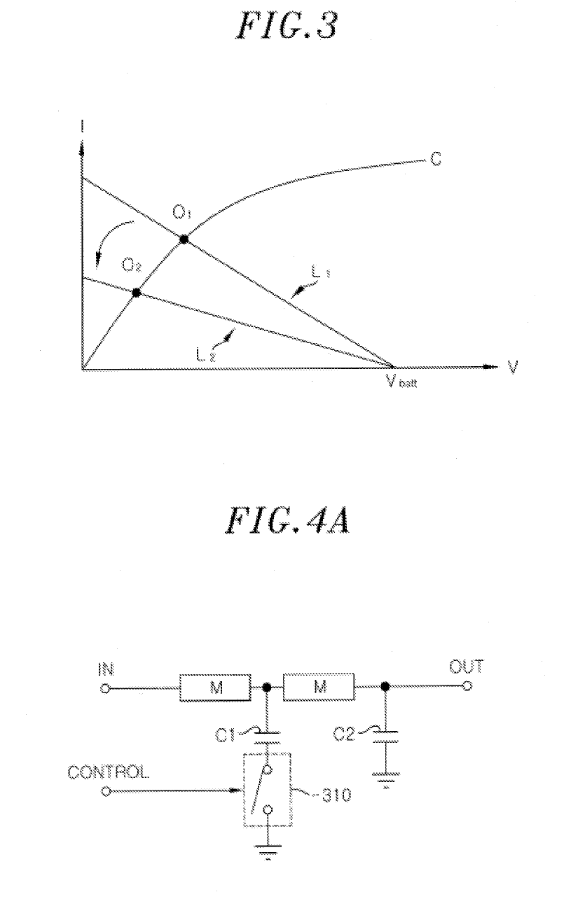

FIG. 4A shows a first embodiment of a variable impedance matching circuit. An input port and an output port of the variable impedance matching circuit of FIG. 4A, which may be externally connected to an output port of power amplifier 100 and a load, respectively, are connected to each other by a microstrip line M (for example, a 50-ohm microstrip line). One end of a first shunt capacitor C1 is connected to an appropriate point of the microstrip line M and the other end thereof is connected to ground via a switch 310. One end of a second capacitor C2 is connected to the output port of the variable impedance matching circuit of FIG. 4A and the other end thereof is connected to ground.

FIG. 4B shows a change of the magnitude of the load impedance Z_{O} on a Smith chart depending on the control of switch 310. When the measured supply voltage V_{SUPPLY} lies between V_{MAX} and the threshold voltage V_{CRITICAL}, controller 400 controls switch 310 to be open so that the load impedance Z_{O} is placed at the point ‘A’ along one curve on the Smith chart. By contrast, when the measured supply voltage V_{SUPPLY} lies between the threshold voltage V_{CRITICAL} and V_{MIN}, controller 400 controls switch 310 to be closed so that the load impedance Z_{O} is placed at the point ‘B’ along the other dotted curve on the Smith chart. Since the magnitude of the load impedance Z_{O} at the point ‘A’ is greater than the magnitude of the load impedance Z_{O} at the point ‘B’, it can be understood that excess linearity of power amplifier 100 is sacrificed at higher supply voltages V_{SUPPLY} to achieve increased power efficiency.

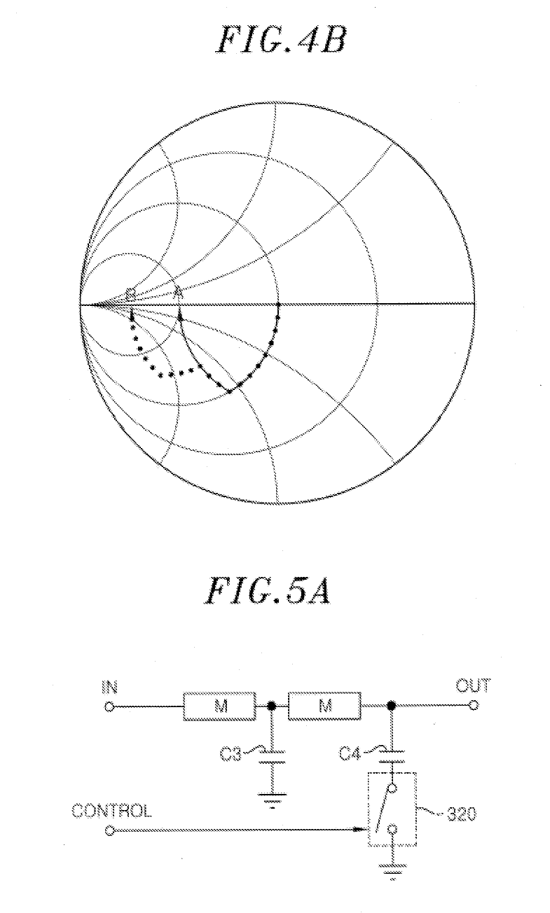

FIG. 5A shows a second embodiment of a variable impedance matching circuit. An input port and an output port of the variable impedance matching circuit of FIG. 5A, which are externally connected to an output port of power amplifier 100 and a load, respectively, are connected to each other by a microstrip line M (for example, a 50-ohm microstrip line). One end of a first shunt capacitor C3 is connected to an appropriate point of the microstrip line M and the other end thereof is connected to ground. One end of a second capacitor C4 is connected to the output port of the variable impedance matching circuit and the other end thereof is connected to ground via a switch 320.

FIG. 5B shows a change of the magnitude of the load impedance Z_{O} on a Smith chart depending on the control of switch 320. When the supply voltage V_{SUPPLY} lies between V_{MAX} and the threshold voltage V_{CRITICAL}, controller 400 controls switch 320 to be open so that the load impedance Z_{O} is placed at the point ‘A’ along one curve on the Smith chart. By contrast, when the supply voltage V_{SUPPLY} lies between the threshold voltage V_{CRITICAL} and V_{MIN}, the controller 400 controls switch 320 to be closed so that the load impedance Z_{O} is placed at the point ‘B’ along the other dotted curve on the Smith chart. Since the magnitude of the load impedance Z_{O} at the point ‘A’ is greater than the magnitude of the load impedance Z_{O} at the point ‘B’, it can be understood that excess linearity of power amplifier 100 is sacrificed at higher supply voltages V_{SUPPLY} to achieve increased power efficiency.

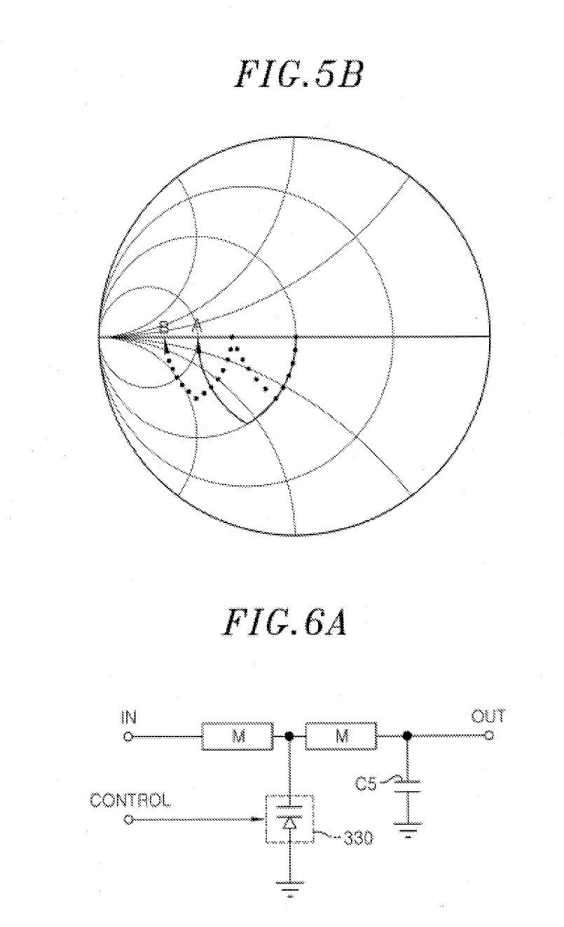

FIG. 6A shows a third embodiment of a variable impedance matching circuit. An input port and an output port of the variable impedance matching circuit of FIG. 6A, which are externally connected to an output port of power amplifier 100 and a load, respectively, are connected each other by a microstrip line M (for example, a 50-ohm microstrip line). One end of a varactor diode 330 is connected to an appropriate point of the microstrip line M and the other end thereof is connected to ground. One end of a capacitor C5 is connected to the output port of variable impedance matching circuit 300 and the other end thereof is connected to ground.

FIG. 6B shows a change of the magnitude of the magnitude of the load impedance Z_{O} on a Smith chart depending on the control of a capacitance of varactor diode 330. The controller 400 controls the varactor diode 330 so that the capacitance of varactor diode 330 in when the supply voltage V_{SUPPLY} lies between V_{MAX} and the threshold voltage V_{CRITICAL} is less than the capacitance of varactor diode 330 when the supply voltage V_{SUPPLY} lies between the threshold voltage V_{CRITICAL} and V_{MIN}. As a result, the load impedance Z_{O} is placed at the point ‘A’ along one curve on the Smith chart when the supply voltage V_{SUPPLY} is greater than the threshold voltage V_{CRITICAL}, and the load impedance Z_{O} is placed at the point ‘B’ along the other dotted curve on the Smith chart when the supply voltage V_{SUPPLY} is less than the threshold voltage V_{CRITICAL}. Since the magnitude of the load impedance Z_{O} at the point ‘A’ is greater than he magnitude of the load impedance Z_{O} at the point ‘B’, it is can be understood that excess linearity of power amplifier 100 is sacrificed at higher supply voltages V_{SUPPLY} to achieve increased power efficiency.

The embodiments of FIGS. 4A, 5A and 6A are just some examples of variable impedance matching circuit 300, and variable impedance matching circuit 300 can be implemented by other circuitry capable of adjusting the magnitude of the load impedance Z_{O}.

Furthermore, in an alternative embodiment of signal amplifier 10 where variable impedance matching circuit 300 employs a varactor diode (e.g., FIG. 6A), controller 400 may control the voltage that is applied to the varactor diode (and therefore the capacitance of the varactor diode) to be a function of the measured supply voltage V_{SUPPLY}, rather than comparing the supply voltage V_{SUPPLY} to a threshold voltage. For example, in one embodiment controller 400 may include a look-up table which maps various values of the measured supply voltage V_{SUPPLY} to corresponding values of a control voltage to be applied to the varactor diode in impedance matching circuit 300 such that a desired load impedance is presented to output port 104 of power amplifier 100 for all values of the supply voltage V_{SUPPLY}. In another example, a processor may employ an equation (e.g., a polynomial fit) to calculate a value of a control voltage to be applied to the varactor diode in response to a value of the measured supply voltage V_{SUPPLY} to control the variable impedance matching circuit 300 to present a desired load impedance Z_{O} to output port 104 of power amplifier 100.

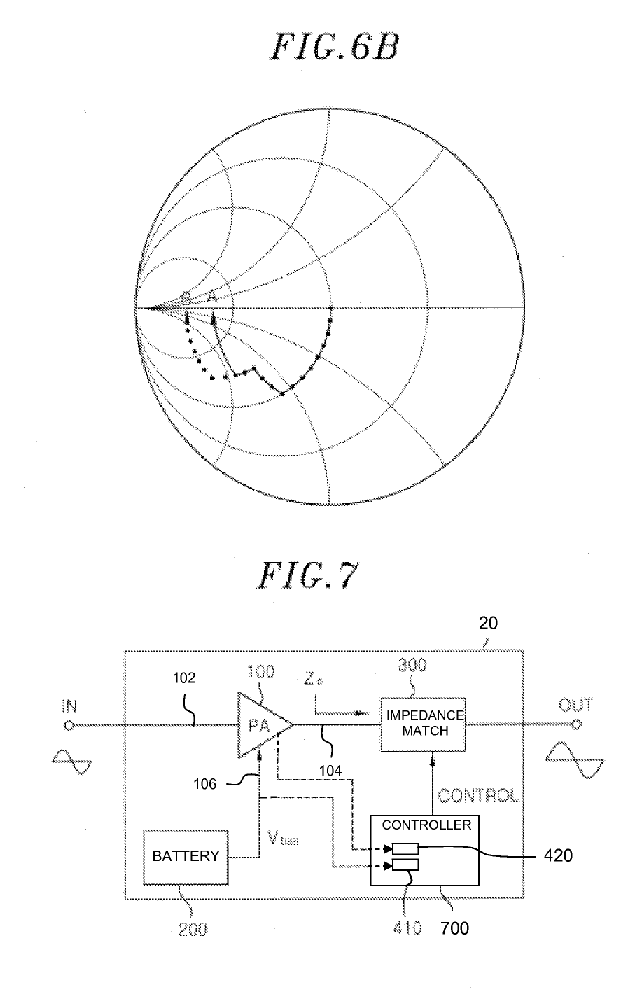

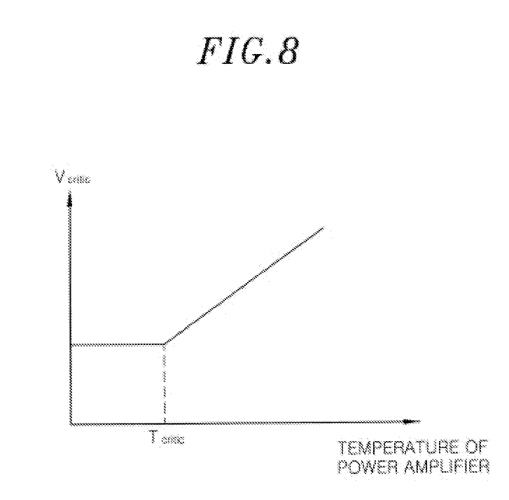

FIG. 7 depicts a schematic configuration of another embodiment of a signal amplifier 20. Elements in FIG. 7 having the same reference numerals or characters as those in FIG. 1 may be the same as each other, and specific descriptions of these elements will be omitted in the description of FIG. 7.

Signal amplifier 20 measures the temperature of power amplifier 100 and adjusts the threshold voltage V_{CRITICAL} based on the measured temperature. Since the power efficiency of a practical power amplifier is not 100%, the power amplifier is inevitably heated and, consequently, the linearity thereof is reduced due to the heat. The reduced linearity at higher temperatures might cause what would be an excess linearity at lower temperatures to be reduced or even to disappear even when the supply voltage V_{SUPPLY} is larger than the threshold voltage V_{CRITICAL}. Therefore, to compensate for the fact that the excess linearity is reduced at higher temperatures, the threshold voltage V_{CRITICAL} may be increased when the temperature of the power amplifier 100 becomes higher. Consequently, in embodiments of signal amplifier 20 the linearity and the power efficiency of power amplifier 100 are exchanged only when the supply voltage V_{SUPPLY} is larger than the increased threshold voltage V_{CRITICAL} and thus the excess linearity is great enough.

When compared with signal amplifier 10, the controller 700 of signal amplifier 20 further includes a temperature measuring unit 420. Temperature measuring unit 420 measures the temperature of the power amplifier 100. Controller 700 adjusts the threshold voltage V_{CRITICAL} based on the measured temperature and adjusts the load impedance Z_{O} such that the magnitude of the load impedance Z_{O} when the supply voltage V_{SUPPLY} lies between V_{MAX} and the adjusted threshold voltage V_{CRITICAL} is greater than the magnitude of the load impedance Z_{O} when the supply voltage V_{SUPPLY} lies between the adjusted threshold voltage V_{CRITICAL} and V_{MIN}. In adjusting the threshold voltage V_{CRITICAL}, it is beneficial that the threshold voltage V_{CRITICAL} is proportional to the temperature of the power amplifier 100, even though it is not necessary to be directly proportional. Furthermore, the threshold voltage V_{CRITICAL} may be predefined as a function of the temperature of power amplifier 100. Furthermore, as shown in FIG. 8, it is also possible to preset T_{CRITICAL} in advance and to maintain the threshold voltage V_{CRITICAL} constantly when the temperature of the power amplifier is smaller than T_{CRITICAL} and to adjust the threshold voltage V_{CRITICAL} to have a proportional magnitude to the temperature only where the temperature is greater than T_{CRITICAL}.

The temperature measuring unit 420 is illustrated as being provided separately from the voltage measuring unit 410 in signal amplifier 20. However, in other embodiments it may be implemented as a single element with the voltage measuring unit 410.

As explained above, when an output voltage of a battery, which is supplied to a power amplifier, is comparatively high, a power efficiency of the power amplifier can be improved by taking advantage of, and sacrificing, an excess linearity of the power amplifier above a specified requirement.

Furthermore, it is possible to control the power efficiency and linearity of the power amplifier by adjusting a load impedance seen from an output port of the power amplifier with simple elements, for example, such as a capacitor and a switch.

Furthermore, by measuring the temperature of the power amplifier and adjusting the load impedance based on the measured temperature, it is possible to improve the power efficiency without failing to meet a minimum linearity requirement for normally operating the power amplifier even in a situation where the temperature becomes somewhat higher.

While the invention has been shown and described with respect to the preferred embodiments only, it will be understood by those skilled in the art that various changes and modifications may be made without departing from the scope of the invention as defined in the following claims.

1. A device, comprising:
a power amplifier, including a supply voltage terminal, an input port and an output port, and the power amplifier being configured to receive a supply voltage at the supply voltage terminal, an input signal through the input port, to amplify the received input signal, and to output an amplified output signal through the output port;
a variable impedance matching circuit having an input terminal connected to the output port of the power amplifier, and having an output terminal for being connected to a load; and
a controller including a voltage measuring unit configured to measure the supply voltage, to compare the measured supply voltage with a threshold voltage, and to control the variable impedance matching circuit based on a result of the comparison so as to adjust a load impedance seen by the power amplifier at its output port.

2. The device of claim 1, wherein the controller is further configured to control the variable impedance matching circuit such that a magnitude of the load impedance when the measured supply voltage is greater than the threshold voltage is adjusted to be greater than the magnitude of the load impedance when the measured supply voltage is less than the threshold voltage.

3. The device of claim 2, wherein the variable impedance matching circuit further comprises:
a microstrip line extending between the input terminal and the output terminal;
a first capacitor with a first end thereof connected to the microstrip line between the input and output terminals and a second end thereof connected to ground via a switch; and
a second capacitor with a first end thereof connected to the output terminal and a second end thereof connected to ground,
wherein the controller is configured to cause the switch to be open when the measured supply voltage is greater than the threshold voltage, and to cause the switch to be closed when the measured supply voltage is less than the threshold voltage.

4. The device of claim 2, wherein the variable impedance matching circuit further comprises:
a microstrip line extending between the input terminal and the output terminal;
a first capacitor with a first end thereof connected to the microstrip line between the input terminal and the output terminal, and a second end thereof connected to ground; and
a second capacitor with a first end thereof connected to the output terminal and a second thereof connected to ground via a switch,
wherein the controller is configured to control the switch to be open when the measured supply voltage is greater than the threshold voltage, and to control the switch to be closed when the measured supply voltage is less than the threshold voltage.

5. The device of claim 2, wherein the variable impedance matching circuit further comprises:
a microstrip line extending between the input terminal and the output terminal;
a varactor diode with a first end thereof connected to the microstrip line between the input terminal and the output terminal and a second end thereof connected to ground; and
a second capacitor with a first end thereof connected to the output terminal and a second end thereof connected to ground,
wherein the controller is configured to control the varactor diode such that a capacitance of the varactor diode when the measured drive voltage is greater than the threshold voltage is adjusted to be less than the capacitance when the measured drive voltage is less than the threshold voltage.

6. The device of claim 2, wherein the controller further includes a temperature measuring unit configured to measure a temperature of the power amplifier and to adjust the threshold voltage based on the measured temperature.

7. The device of claim 1, wherein the controller further includes a temperature measuring unit configured to measure a temperature of the power amplifier and to adjust the threshold voltage based on the measured temperature.

8. The device of claim 1, further comprising a battery having a battery voltage, and wherein the supply voltage is the battery voltage, and wherein the controller is configured to compare the battery voltage with the threshold voltage, and to control the variable impedance matching circuit based on a result of the comparison of the battery voltage and the threshold voltage so as to adjust a load impedance seen by the power amplifier at its output port.

9. A method of amplifying a signal, comprising:
providing the signal to an input port of a power amplifier;
providing a supply voltage to the power amplifier;
amplifying the signal with the power amplifier and outputting an amplified output signal at an output port of the power amplifier;
measuring the supply voltage;
comparing the measured supply voltage with a threshold voltage; and
adjusting a load impedance seen by the power amplifier at its output port based on a result of the comparison.

10. The method of claim 9, wherein the load impedance is adjusted such that a magnitude of the load impedance when the measured drive voltage is greater than the threshold voltage is greater than the magnitude of the load impedance when the measured drive voltage is less than the threshold voltage.

11. The method of claim 9, further comprising:
measuring a temperature of the power amplifier; and
adjusting the threshold voltage based on the temperature measurement.

12. The method of claim [[8]]2, further comprising:
measuring a temperature of the power amplifier; and
adjusting the threshold voltage based on a result of the temperature measurement.

13. The method of claim 9, wherein adjusting a load impedance seen by the power amplifier at its output port comprises adjusting a voltage applied to a varactor diode in an impedance matching circuit connected to the output port of the power amplifier.

14. The method of claim 9, wherein adjusting a load impedance seen by the power amplifier at its output port comprises selectively connecting to ground and disconnecting from ground a capacitor in an impedance matching circuit connected to the output port of the power amplifier.

15. A device, comprising:
a power amplifier, including a supply voltage terminal, an input port and an output port, and the power amplifier being configured to receive a supply voltage at the supply voltage terminal, an input signal through the input port, to amplify the received input signal, and to output an amplified output signal through the output port; and
circuitry configured to adjust a load impedance seen by the power amplifier at its output port,
wherein when the supply voltage has a first voltage value the circuitry adjusts the load impedance to have a first impedance value, and when the supply voltage has a second voltage value less than the first voltage value, the circuitry adjusts the load impedance to have a second impedance value less than the first impedance value.

16. The device of claim 15, wherein the circuitry includes a variable impedance matching circuit having an input terminal connected to the output port of the power amplifier, and having an output terminal for being connected to a load.

17. The device of claim 16, wherein the variable impedance matching circuit includes a varactor diode, and wherein the load impedance is adjusted by a voltage applied to the varactor diode.

18. The device of claim 15, wherein the circuitry adjusts the load impedance in response to a temperature of the power amplifier.

19. The device of claim 15, further comprising a battery having a battery voltage, and wherein the supply voltage is the battery voltage, and wherein the battery voltage has the first voltage value the circuitry adjusts the load impedance to have the first impedance value, and when the battery voltage has the second voltage value less than the first voltage value, the circuitry adjusts the load impedance to have the second impedance value less than the first impedance value.

20. The device of claim 1, wherein the controller is configured such that when the supply voltage exceeds the threshold, the controller adjusts the load impedance seen by the power amplifier at its output port such that a linearity of the power amplifier is decreased.
